(19) United States
(12) Patent Application Publication
(10) Pub. No.: US 2022/0187342 A1
(43) Pub. Date: Jun. 16, 2022

(54) MICROELECTRONIC TEST INTERFACE SUBSTRATES, DEVICES, AND METHODS OF MANUFACTURE THEREOF VERTICAL AND HORIZONTAL ELECTRICAL SHIELD ON INNER LAYER CONNECTING CONDUCTOR VIAS AND CONDUCTOR TRACES OF ANY POSITIONS ON BUILDUP REDISTRIBUTION LAYER SYSTEM

(71) Applicant: Raymond Won Bae, Danville, CA (US)

(72) Inventor: Raymond Won Bae, Danville, CA (US)

(21) Appl. No.: 17/515,402

(22) Filed: Oct. 30, 2021

Related U.S. Application Data
(60) Provisional application No. 63/199,222, filed on Dec. 15, 2020.

(51) Int. Cl. G01R 3/00; G01R 31/28

(52) U.S. Cl. CPC G01R 3/00; G01R 31/2886

(57) ABSTRACT

An embodiment of the present invention provides a method and system of manufacturing a redistribution platform comprising and providing a base substrate; buildup layer level thereof vertical and/or horizontal electrical shield on Inner layer connecting conductor vias and traces in any positions in the buildup redistribution system.

### TECHNICAL FIELD

An embodiment of the present invention relates generally to microelectronic buildup redistribution layer system.

### BACKGROUND

Electromagnetic interference (EMI) is prevalent throughout the conductor circuits in the test interface substate. Therefore, signal integrity (SI) and/or power integrity (PI) controlled conductors are usually protected with plane and/or ground layers on top, bottom, or both. This shielding reduces electrical noise and reduces its impact on signals and lowers electromagnetic radiation. Shielding also prevents crosstalk between near or surrounding conductors.

The current method of test interface substrate manufacturing thereof involves EMI protection by adding plane and/or ground layers on top, bottom, or both, but limited or no protection on the inner connecting conductor vias between layers. Hence it creates the not only the low electrical performance, increase in layer counts with the increase in the delivery lead-time but decrease in reliability with the increase in the cost. Modern consumer and industrial electronics, cellular phones, mobile devices, and computing systems, are providing increasing levels of volume production to require more and more faster, flexible, and reliable test interface substrate to meet the market demands. Research and development in the existing technologies can take a myriad of different directions.

As users become more empowered with the growth of computing devices, new and old paradigms begin to take advantage of this new device space. There are many technological solutions to take advantage of this new device capability and device miniaturization. However, reliable testing and faster delivery of wafers through new devices has become a concern for manufactures.

Thus, a need remains for a microelectronic buildup redistribution layer system for testing of wafers and devices. In view of the ever-increasing high-speed applications and performance, better commercial competitive pressures, along with growing consumer expectations and the diminishing opportunities for meaningful product differentiation in the marketplace, it is increasingly critical that answers be found to these problems. Additionally, the need to provide manufacturing capabilities of redistribution system layer to layer buildup process to provide the EMI vertical shield on interconnecting conductor vias. This improves efficiencies and performance, reduce the number of total layers, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a microelectronic buildup redistribution layer system, including: a base carrier substrate; conductor traces and a dielectric structure on the substrate, including a plurality of multi-layers.

An embodiment of the present invention provides a method of manufacture thereof providing vertical EMI shield on the interconnecting conductor vias and surrounding between layers. This reduces the number of layers, reduce the conductor length; hence, increase the testing performance, increasing yield, reducing the lead-time and reduce the cost in the total of test interface substrate manufacturing. Microelectronic buildup redistribution layer system including: providing a base carrier substrate; forming a plurality of multi-layers on the substrate, conductor traces, conductor vias and a dielectric structure on the substrate.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a schematic side view of a probe card system in an embodiment of the present invention microelectronics test interface redistribution layer system 300 is integrated.

FIG. 2 schematic view of an embodiment of microelectronic test interface substrate system with bottom base carrier substrate 500 view and microelectronic buildup redistribution layer 300 top view with conductor traces and test pads.

FIG. 3 is a schematic cross-sectional side view of an embodiment of microelectronic test interface substrate system 700 with the 3 buildup redistribution layers; 101, 102 and 103, and the vertical buildup redistribution shields connected to the interface base substrate system 500 with ground layer 401.

FIG. 4 is a schematic cross-sectional side view of an embodiment of microelectronic test interface substrate system 700 along lines; 20-20, 30-30, 40-40, 50-50, 60-60 and 70-70 in FIG. 3.

FIG. 5 is a schematic Top view of 1^{st} buildup redistribution layer system 101 with the dotted box showing the side view conductors in FIG. 4 line 20-20.

FIG. 6 is a schematic Top view of 1^{st} buildup redistribution layer system 101 with the dotted box showing the side view conductors in FIG. 4 line 30-30.

FIG. 7 a schematic Top view of 2^{nd} buildup redistribution layer system 102 with the dotted box showing the side view conductors in FIG. 4 line 40-40.

FIG. 8 is a schematic Top view of 2^{nd} buildup redistribution layer system 102 with the dotted box showing the side view conductors in FIG. 4 line 50-50.

FIG. 9 is a schematic Top view of 3^{rd} buildup redistribution layer system 103 with the dotted box showing the side view conductors in FIG. 4 line 60-60.

FIG. 10 is a schematic Top view of 3^{rd} buildup redistribution layer system 103 with the dotted box showing the side view conductors in FIG. 4 line 70-70.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

In this embodiment, the buildup redistribution vertical electrical shield on Inner layer connecting conductor vias and surrounding is shown only connected to the single ground layer from the base interface substrate. However, it can be routed and connected with any layers and conductors.

The designation and usage of the term first, second, third, etc. is for convenience and clarity and is not meant limit a particular order. The steps or processes described can be performed in any order to implement the claimed subject matter.

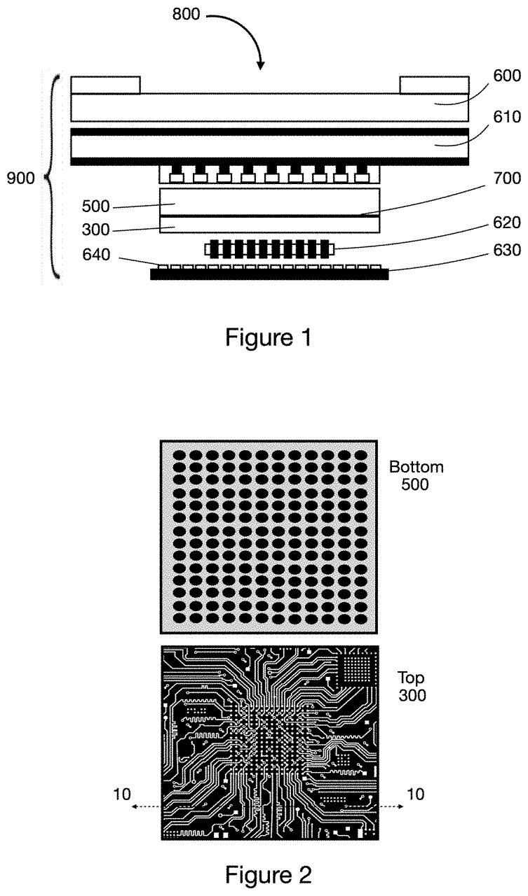

Referring now to FIG. 1, therein is shown an embodiment of microelectronic test interface substrate system schematic side view of a probe card system 800 and an embodiment of the present invention 700 is integrated. The system 800 is a system for providing interconnection between different devices. For example, the system 800 can be a component in a wafer testing system 900 or a substrate in an integrated circuit packaging system. As an example, the wafer testing system 900 can include a mechanical stiffener 600, a printed circuit board 610, a redistribution test interface platform 700 consist of the base carrier substrate 500 and redistribution substate platform 300, and a probe head 620. The mechanical stiffener 600, the printed circuit board 610, the redistribution test interface platform 700, and the probe head 620 are components for a system to test a semiconductor wafer 630. The semiconductor wafer 630 can include a die 640 with electronic components, such as circuits, integrated circuits, logic, integrated logic, or a combination thereof fabricated thereon.

Referring now to FIG. 2, therein is shown an embodiment of microelectronic test interface substrate system top view of microelectronic buildup redistribution layer 300 of FIG. 1 and bottom view of base carrier substrate 500 of FIG. 1 of the redistribution test interface substrate platform 700. The bottom conductor pads of the test interface substate are interconnecting toward the printed circuit board 610 of FIG. 1. The top side of the test interface substrates are interconnecting to the probe head 620 of FIG. 1. For wafer chip 630 of FIG. 1 and other logic and integrated devices to be tested.

The redistribution platform 700 is a structure for providing interconnection between two devices. For example, the redistribution platform 700 can be a space transformer, a redistribution structure for a multi-die package, or a combination thereof. The redistribution platform 700 can provide electrical and functional connectivity between semiconductor wafer 630, the die 640, or a combination thereof, and the rest of the redistribution system 800.

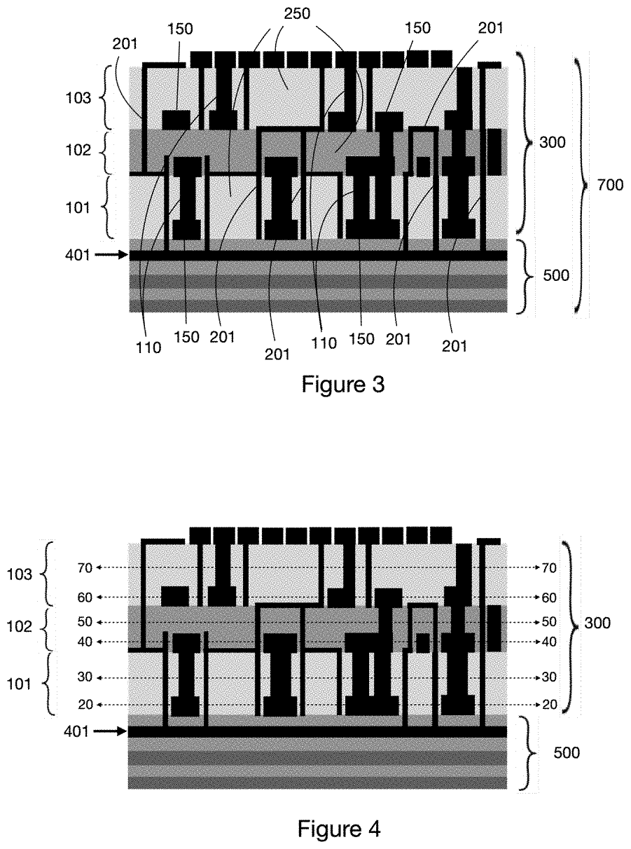

Referring now to FIG. 3, therein is shown an embodiment of microelectronic test interface substrate system cross-sectional side view of the test interface substrate system 700; base carrier substrate 500, the microelectronics redistribution system 300; 1^{st} redistribution layer 101, 2^{nd} redistribution layer 102 and 3^{rd} redistribution layer 103. For illustrative purpose, the redistribution conductors and shields are depicted having a similar shape from the side view, although it is understood that the system 700 can have a different shape and more or less layers than the illustration. For example, the redistribution conductor system in 101, 102, and 103 can have any shapes and thickness to meet the needs of testing interface design requirement, such as a square, or rectangular shape, a triangular shape, pentagonal shape, or any other polygonal shapes and curves.

For illustrate purpose, the microelectronic redistribution platform 300 consists only of 3 layers 101, 102, and 103. To distinguish each layer, dielectric system 250 of each layer is colored in difference in contrast. For example, the buildup redistribution layer system 102 dielectric is colored darker than the buildup redistribution layers 102 and 103. The total test interface substrate redistribution layer counts can be of more or less.

For illustrate purpose, the buildup redistribution shield conductors 201 are connected to the base interface substrate system 500 ground layer 401. However, it can be routed and connected with any layers and conductors.

The buildup redistribution layer conductor system 150, Interconnecting via conductor system 201 and shield conductor are depicted having a similar shape from the side view, although it is understood that the buildup redistribution system 300 can have a different shape and more or less layers than the illustration. For example, the redistribution conductor system in 101, 102, and 103 can have any shapes and thickness to meet the needs of testing interface design requirement, such as a square, or rectangular shape, a triangular shape, pentagonal shape, or any other polygonal shapes and curves.

The microelectronics buildup redistribution system 300 layers can be signal layer, ground layer, power and plane layer or the combination thereof.

Referring now to FIG. 4, therein is shown an embodiment of microelectronic test interface substrate system cross-sectional side view of the buildup redistribution test interface substrate system 700 of FIG. 3. Each buildup redistribution layer is line crossed at the conductor pad level and the middle section of layer to illustrate the vertical buildup redistribution shield conductors. For example, the buildup redistribution layer 101 has two crossed lines; 20-20 and 30-30, buildup redistribution layer 102; 40-40 and 50-50 and buildup redistribution layer 103; 60-60 and 70-70 crossed lines.

The platform 500 is a base carrier substrate providing interconnection between redistribution platform 300. For illustrative purposes, the redistribution platform 300 can provide electrical and functional connectivity between the semiconductor wafer, semiconductor dice, or a combination thereof for system testing, such as wafer testing, die testing, package testing, or inter-package testing.

The base carrier substrate 500 can be a rigid foundation or base layer for the redistribution player platform 300. The substrate 500 can include an electrically insulating material, such as a ceramic based or polymer composite based material.

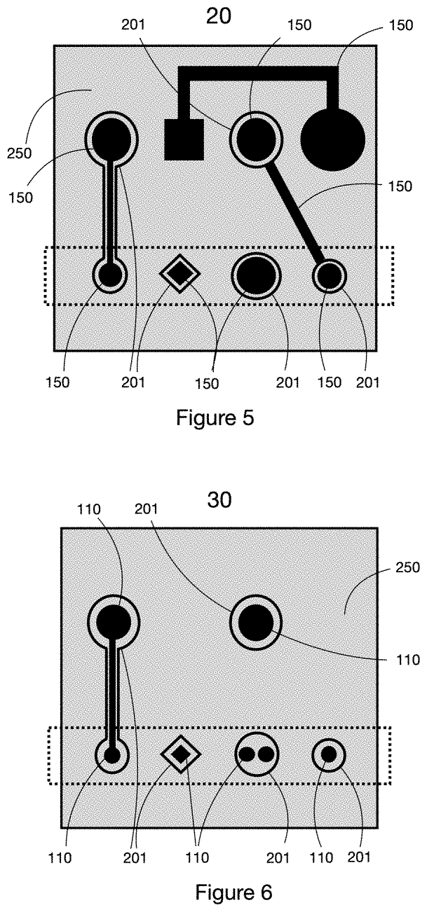

Referring now to FIG. 5, therein is shown an embodiment of microelectronic test interface substrate system top view of the 1^{st} buildup redistribution layer crossed line 20-20 in FIG. 4. For illustrate purpose, the conductors in dotted box depict the side view conductors along crossed line 20-20.

In FIG. 5, the conductors 150 are shown with shield conductor 201 and without shield conductor. The shield conductors can be vertically buildup completely encompassing and/or partially encompassing the conductors to any level in the buildup redistribution system 300.

Referring now to FIG. 6, therein is shown an embodiment of microelectronic test interface substrate system top view of the 1^{st} buildup redistribution layer crossed line 30-30 in FIG. 4. For illustrate purpose, the conductors in dotted box depict the side view conductors along crossed line 30-30.

Crossed line 30-30 represents the middle of 1^{st} buildup redistribution layer. This embodiment depicts the layer buildup redistribution interconnecting conductor vias 110 and buildup redistribution shields 201 encompassing them.

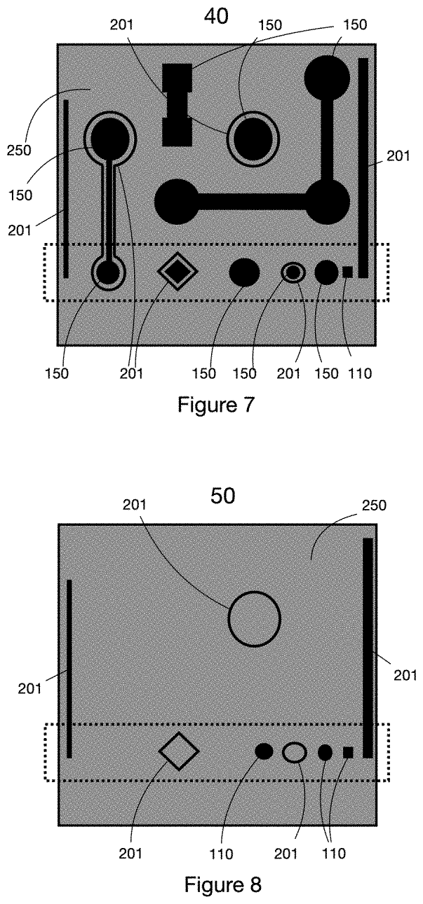

Referring now to FIG. 7, therein is shown an embodiment of microelectronic test interface substrate system top view of the 2^{nd} buildup redistribution layer crossed line 40-40 in FIG. 4. For illustrate purpose, the conductors in dotted box depict the side view conductors along crossed line 40-40.

FIG. 7 illustrates the buildup redistribution test interface substrate side shields 201. This buildup redistribution shield conductor can be useful to prevent EMI from the surrounding systems.

Referring now to FIG. 8, therein is shown an embodiment of microelectronic test interface substrate system top view of the 2^{nd} buildup redistribution layer crossed line 50-50 in FIG. 4. For illustrate purpose, the conductors in dotted box depict the side view conductors along crossed line 50-50.

Crossed line 50-50 represents the middle of 2^{nd} buildup redistribution layer. This embodiment depicts the layer buildup redistribution interconnecting conductor vias 110 and buildup redistribution shields 201.

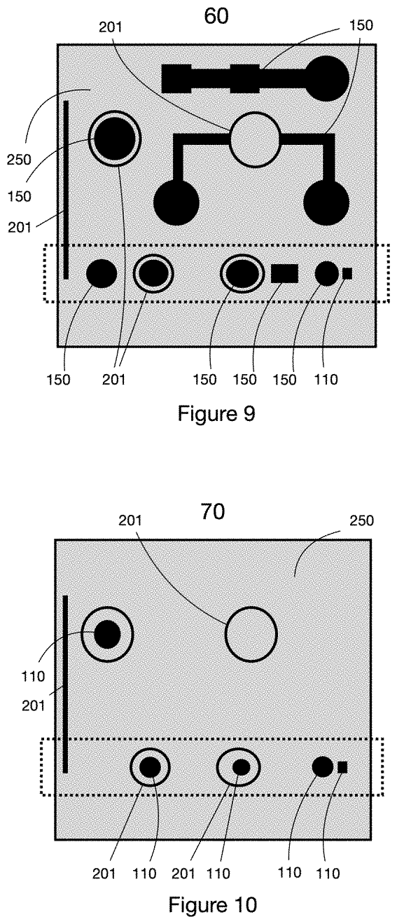

Referring now to FIG. 9, therein is shown an embodiment of microelectronic test interface substrate system top view of the 3^{rd} buildup redistribution layer crossed line 60-60 in FIG. 4. For illustrate purpose, the conductors in dotted box depict the side view conductors along crossed line 60-60.

For illustrate purpose, the left side buildup redistribution shield 201 is build up from 2nd redistribution layer. However, right side buildup redistribution shield 201 in FIG. 8 is not shown.

Referring now to FIG. 10, therein is shown an embodiment of microelectronic test interface substrate system top view of the 3^{rd} buildup redistribution layer crossed line 70-70 in FIG. 4. For illustrate purpose, the conductors in dotted box depict the side view conductors along crossed line 70-70.

Crossed line 70-70 represents the middle of 3^{rd} buildup redistribution layer. This embodiment depicts the layer buildup redistribution interconnecting conductor vias 110 and buildup redistribution shields 201 encompassing them

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of a foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. Microelectronic buildup redistribution layer system comprising; A, a substrate comprising base carrier, dielectric, conductor traces, conductor vias connecting layers. B, a microelectronic redistribution layers include a buildup process on base carrier. C, a microelectronic redistribution layers included the different or same layers.

2. Microelectronic buildup redistribution layer system of claim 1, wherein the via conductor provide an interlocking or connecting function with the top or bottom layer conductor.

3. Microelectronic buildup redistribution layer system of claim 1, wherein the base carrier substrate is a ceramic material in construction of single or multi-layers.

4. Microelectronic buildup redistribution layer system of claim 1, wherein the base carrier substrate is an organic, printed circuit board, material in construction of single or multi-layers.

5. Microelectronic buildup redistribution layer system of claim 1, wherein the base carrier substrate is a wafer.

6. Microelectronic buildup redistribution layer system of claim 1, wherein the base carrier substrate is a glass.

7. Microelectronic buildup redistribution layer system of claim 1, wherein the base carrier substrate is a quartz.

8. Microelectronic buildup redistribution layer system of claim 1, wherein the dielectric is a polyimide-based polymer material.

9. Microelectronic buildup redistribution layer system of claim 1, wherein the dielectric is an epoxy-based polymer material.

10. Microelectronic buildup redistribution layer system of claim 1, wherein the dielectric is a resin-based polymer material.

11. Microelectronic buildup redistribution layer system of claim 1, wherein the base carrier substrate includes a through substrate via in the substrate and connected to the conductor traces.

12. Microelectronic buildup redistribution layer system of claim 1, wherein the substrate is a polymer composite substrate.

13. A method of manufacturing microelectronic buildup redistribution layer system comprising and providing; A, a substrate forming a plurality of microelectronic redistribution layers on the substrate, the redistributions layers including a dielectric layer and conductive (conductor) traces. B, a substrate forming a multi-layer structure by cross-linking or connecting layers by via conductor.

14. The method of claim 13, wherein forming the microelectronic redistribution layers includes the polymer layer as a polyimide-based polymer material.

15. The method of claim 13, wherein forming the redistribution layers includes the polymer layer as an epoxy-based polymer material.

16. The method of claim 13, wherein providing the substrate includes providing the substrate including a through substrate vias and forming the redistribution layers include the conductive traces connected to the through substrate via.

17. The method of claim 13, wherein providing the substrate includes providing a ceramic substrate.

18. The method of claim 13, wherein providing the substrate includes providing a polymer composite substrate.

19. The method of claim 13, wherein providing the substrate includes providing many base materials.

20. The method of claim 13, wherein proving the substrate includes providing no lamination process for the multi-layered redistribution system.

21. The method of claim 13, wherein proving the substrate includes layer to layer buildup process for the multi-layered redistribution system.

22. The method of claim 13, wherein proving the substrate includes vertical, horizonal and combination thereof shield protection by buildup redistribution layer system.
